(19) United States
(12) Patent Application Publication
(10) Pub. No.: US 2013/0037104 A1
(43) Pub. Date: Feb. 14, 2013

(54) NANOPARTICLE ENHANCED SOLAR-CELL ABSORBER EFFICIENCY

(71) Applicant: Mats I. Larsson, Sunnyvale, CA (US)

(72) Inventor: Mats I. Larsson, Sunnyvale, CA (US)

(73) Assignee: MiaSole, Santa Clara, CA (US)

(21) Appl. No.: 13/207,198

(22) Filed: Aug. 10, 2011

(51) Int. Cl. H01L 31/0232; H01L 31/18; B82Y 20/00

(52) U.S. Cl. 136/257; 438/72; 977/948; 257/E31.127

(57) ABSTRACT

Embodiment methods and structures include a resonant plasmonic nanostructure located within a thin-film solar cell. This plasmonic nanostructure may trap light and thereby improve the efficiency and light absorption of the cell without increasing physical thickness. In various embodiments, the plasmonic nanostructure may be located within a p-type semiconductor layer of the solar cell. In further embodiments, the index of refraction may vary within the p-type semiconductor layer.

### BACKGROUND

Copper indium diselenide (CuInSe₂, or CIS) and its higher band gap variants copper indium gallium diselenide (Cu(In,Ga)Se₂, or CIGS), copper indium aluminum diselenide (Cu(In,Al)Se₂), copper indium gallium aluminum diselenide (Cu(In,Ga,Al)Se₂) and any of these compounds with sulfur replacing some of the selenium represent a group of materials, are referred to as copper indium selenide CIS based alloys. These materials have desirable properties for use as the absorber layer in thin-film solar cells. To function as a solar absorber layer, these materials should be p-type semiconductors. This may be accomplished by establishing a slight deficiency in copper, while maintaining a chalcopyrite crystalline structure. In CIGS, gallium usually replaces 20% to 30% of the normal indium content to raise the band gap; however, there are significant and useful variations outside of this range. If gallium is replaced by aluminum, smaller amounts of aluminum are used to achieve the same band gap.

### SUMMARY

One embodiment of this invention provides a solar cell including a first electrode, at least one first conductivity type semiconductor absorber layer located over the first electrode, a plasmonic nanostructure located within the semiconductor absorber layer, a second conductivity type semiconductor layer located over the semiconductor absorber layer, and a second electrode located over the second conductivity type semiconductor layer.

Further embodiments include a method of producing a solar cell including the steps of providing a substrate, depositing a first electrode over a substrate, depositing a first portion of a first conductivity type semiconductor absorber layer over the first electrode, forming a plasmonic nanostructure over the first portion, depositing a second portion of the first conductivity type semiconductor absorber layer over the plasmonic nanostructure, depositing a second conductivity type semiconductor layer over the second portion, and depositing a second electrode over the second conductivity type semiconductor layer.

### BRIEF DESCRIPTION OF THE DRAWINGS

FIG. 1 is a schematic side cross-sectional view of a CIS based solar cell according to one embodiment of the invention.

FIG. 2 shows a delta layer of nanoparticles located within a semiconductor absorber layer.

FIG. 3 shows a highly simplified schematic diagram of a modular sputtering apparatus that can be used to manufacture solar cells.

FIG. 4 shows a highly simplified schematic diagram of a modular sputtering apparatus that can be used to create a graded semiconductor layer in embodiment solar cells.

### DETAILED DESCRIPTION

Thin-film solar cell designs often must balance the physical thickness of the cells against the ability to absorb more light. A thicker solar cell may absorb more radiation, particularly the near band gap light that some thin-film solar cells have trouble absorbing. However, thicker cells cost more to produce. Thicker cells may also be less efficient if the minority carrier diffusion length is not long enough relative to the physical thickness of the cell. A solution to this balancing problem is trapping or concentrating light so that a physically thin cell may behave as if “optically” thick. Trapping light within the solar cell may improve radiation absorption and efficiency while allowing decreased physical thickness and cost.

One manner of trapping light relies on plasmonics. A plasmon is a quantum of oscillation of the free electron density. A surface plasmon is a quantum of electron oscillation at the interface between two materials, such as between a metal and a dielectric. Surface plasmons can be excited by photons. Thin-film solar cells may include metallic nanostructure(s), such as nanoparticles that support surface plasmons excited by incident light. The metallic nanoparticles may be designed to act as antennas temporarily storing the energy from the incident light as localized surface plasmons (i.e., coupling the plasmonic near-field to the semiconductor). These surface plasmons may then cause the creation of electron-hole pairs in the semiconductor. The nanostructures may also reflect the sun light toward the p-n junction.

Embodiment methods and structures include a resonant plasmonic nanostructure located within a thin-film solar cell. This plasmonic nanostructure may trap light and thereby improve the efficiency and light absorption of the cell without increasing a physical thickness of the cell. In various embodiments, the plasmonic nanostructure may be located within an absorber layer (e.g., p-type semiconductor layer) of the solar cell. In further embodiments, the index of refraction may vary within the p-type semiconductor layer. A plasmonic nanostructure is any metal or electrically conductive feature having at least one dimension less than one micron, preferably two or three dimensions less than a micron, which can cause a plasmon effect within the semiconductor absorber. Examples of such nanostructures include nanoparticles having a diameter or width below 1 micron, such as below 500 nm, or thin metal films having a rough or corrugated surface with features having at least one dimension below 1 micron, which face the p-n junction of the solar cell. The nanoparticles may have a cylindrical shape or any other suitable shape, such as regular or irregular shape having an oval or polygonal cross section shape.

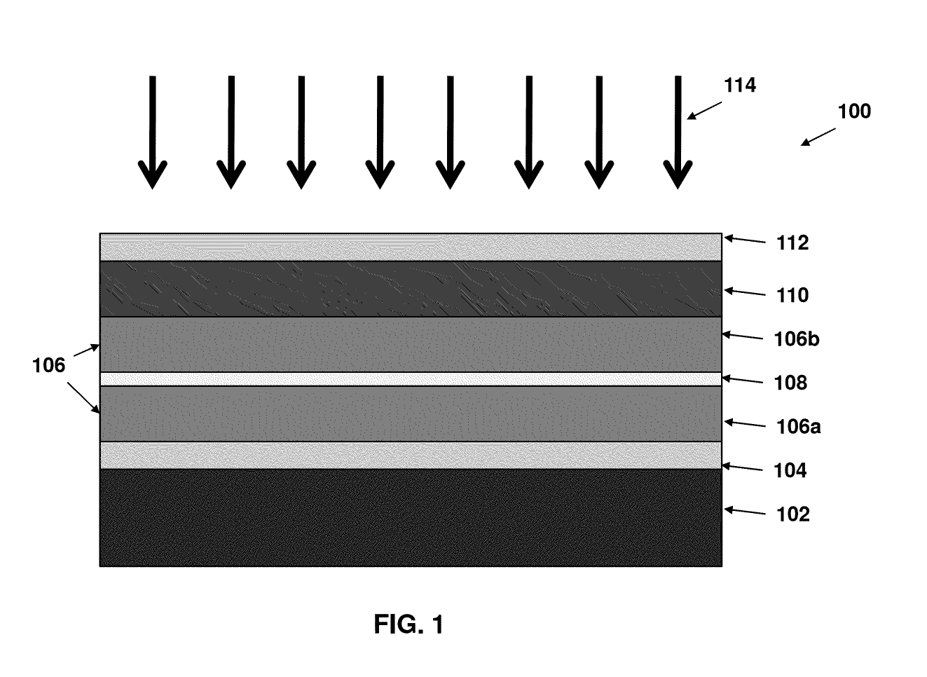

FIG. 1 illustrates an embodiment thin-film solar cell 100. A solar cell 100 may include a substrate 102. In various embodiments, the substrate 102 may be a foil web, for example, a metal web substrate, a polymer web substrate, or a polymer coated metal web substrate. Any suitable materials may be used for the foil web. For example, metal (e.g., stainless steel, aluminum, or titanium) or thermally stable polymers (e.g., polyimide or the like) may be used.

An electrode 104 may be formed above the substrate 102. In various embodiments, the electrode 104 may be any suitable transition metal, for example but not limited to Mo, W, Ta, V, Ti, Nb, and Zr. In further embodiments, the electrode 104 may further comprise an alkali element or an alkali compound, such as sodium. The electrode 104 may include a lattice distortion element, such as oxygen or a lattice distortion compound, such a molybdenum oxide. In some embodiments, the electrode 104 may include multiple sublayers, such as an alkali diffusion barrier sublayer (e.g., a dense Mo layer) adjacent to the substrate 102 and/or a sublayer of a second transition metal (e.g., less dense Mo layer) on opposite sides of a sodium and/or oxygen containing Mo layer.

A first portion 106a of a p-type semiconductor layer 106 capable of absorbing sunlight 114 may be formed over the electrode 104. In preferred embodiments, the p-type semiconductor absorber layer 106 may comprise a CIS based alloy material selected from copper indium selenide, copper indium gallium selenide, copper indium aluminum selenide, or combinations thereof. Layer 106 may have a stoichiometric composition having a Group I to Group III to Group VI atomic ratio of about 1:1:2, or a non-stoichiometric composition having an atomic ratio of other than about 1:1:2. Preferably, layer 106 is slightly copper deficient and has slightly less than one copper atom for each one of Group III atom and each two of Group VI atoms. While a CIS type (e.g., CIGS) p-type absorber layer is described above, other materials (e.g., CdTe) and/or opposite conductivity type (e.g., n-type) may be used for the absorber layer. Further embodiments may include one or more other solar absorbing materials, such as CdTe, GaAs, Ge, SiGe, organic photovoltaic materials, and various forms of silicon (e.g., amorphous, polycrystalline and single crystal silicon).

A plasmonic nanostructure 108 may be deposited on the first portion 106a. The plasmonic nanostructure 108 may comprise a delta layer of nanoparticles. These nanoparticles may be various metal or metal alloys having plasmonic properties, such as gold, silver, etc. The nanoparticles may have a diameter (or width for non-cylindrical nanoparticles) of 1-500 nm, such as 5-20 nm. The layer 108 may have a thickness of less than 500 nm, such as 25-200 nm, for example 50-100 nm. A second portion 106b of the p-type semiconductor layer 106 may be deposited over the plasmonic nanostructure 108. The second portion 106b of the p-type semiconductor layer may have a similar composition to the first portion 106a.

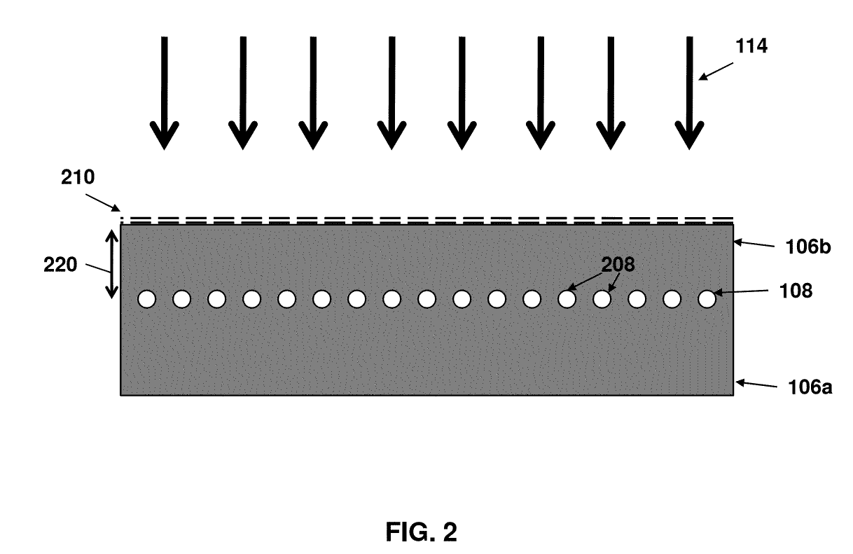

An n-type semiconductor layer 110 may be deposited over the second portion 106b of the p-type semiconductor absorber layer. The n-type semiconductor layer 110 may comprise any suitable n-type semiconductor materials, for example, but not limited to, Zinc Sulfide (ZnS), Zinc Selenide (ZnSe), or Cadmium Sulfide (CdS). Layer 110 forms a p-n junction 210 shown in FIG. 2 with portion 106b of layer 106.

A second electrode 112 may be deposited over the n-type semiconductor layer 110. The second electrode 112 may be transparent to allow sunlight 114 to shine through. The second electrode 112 may comprise multiple transparent conductive layers, for example, but not limited to, one or more of an Indium Tin Oxide (ITO), Zinc Oxide (ZnO) or Aluminum Zinc Oxide (AZO) layers. The second electrode may also include an optional resistive Aluminum Zinc Oxide (RAZO) layer. In various embodiments, the transparent top electrode 112 may comprise any other suitable materials, such as doped ZnO or SnO.

Optionally, one or more antireflection (AR) films (not shown) may be deposited over the transparent top electrode 112, to optimize the light absorption in the solar cell 100, and/or current collection grid lines may be deposited over the top conducting oxide.

FIG. 2 illustrates the placement of the plasmonic nanostructure 108 between the two portions 106a and 106b of the p-type semiconductor absorber layer. The plasmonic nanostructure 108 may be a delta layer of nanoparticles 208. The nanoparticles 208 may be various metal or metal alloys having plasmonic properties, such as gold, such that sunlight 114 may excite surface plasmons. In this way, the nanoparticles 208 may effectively trap the light from incident solar radiation 114. The surrounding semiconductor material may absorb the trapped light from the surface plasmons thereby increasing total absorption by the p-type semiconductor absorber layer 106. The semiconductor material's rate of absorption may be higher than the nanoparticles' plasmon decay rate in order to avoid the stored optical energy being dissipated into ohmic losses in the nanoparticles 208.

The plasmonic nanoparticles 208 may be formed in a delta layer. This delta layer may be located a distance 220 from the p-n junction 210 where the upper portion 106b of the p-type semiconductor absorber layer meets the n-type semiconductor layer 110. The distance 220 may also be viewed as the thickness of the second portion 106b of the p-type semiconductor layer. The distance 220 may be the same as or greater than the sum of the depletion width of the p-n junction 210 plus the diffusion length of the p-type semiconductor's minority carrier (i.e., electrons). This distance may minimize loss of electrons generated from the nanoparticles' surface plasmons due to trap-state assisted recombination.

As an example, in some embodiments, the depletion width may be 0.2-0.3 μm. The minority carrier diffusion length may be 0.1-0.2 μm. Therefore, the delta layer may be a distance 220 of about 0.3-0.5 μm beneath the p-n junction 210. In some embodiments, this distance 220 may be about a third of the total thickness of the p-type semiconductor layer 106. In other words, the thickness of portion 106b of layer 106 may be at least 0.3 to 0.5 microns, such as 0.3 to 0.7 microns, and the thickness of layer 106a may be 0.6 to 1.5, such as 0.6 to 1 microns.

In one embodiment, the first portion 106a and the second portion 106b of the p-type semiconductor layer may have different indexes of optical refraction. For example, the second portion 106b (i.e., the portion above the plasmonic nanostructure and closer to the p-n junction 210) may have a higher index of optical refraction. A high index of refraction may reflect light to couple the optical modes towards the p-n junction 210. For example, the second portion 106b may have an index of optical refraction (i.e., the real portion of the index, n) of about 2 to 2.5, such as about 2.2. The first portion 106a may have an index of optical refraction, n, of about 1.3 to 1.8, such as about 1.5.

In further embodiments, the index of optical refraction may be graded throughout the p-type semiconductor layer 106. For example, the index of optical refraction may be lower near the p-type semiconductor layer's junction with the electrode 104 and then increase through the layer 106 towards the p-n junction 210. The index of refraction may be graded by varying the density, grain size, porosity, and/or composition of the p-type semiconductor layer 106 during production. Higher density may correspond to a higher index of refraction. Density may be controlled by varying of the pore size and/or pore volume of semiconductor of layer 106.

The index of optical refraction may have a nonzero extinction coefficient representing the amount of absorption loss from propagating through the material. In further embodiments, the positions of the delta layer may be selected based on the p-type semiconductor layer's extinction coefficient (i.e., as a function of 4πk/λ, where k is the extinction coefficient/imaginary part of index of refraction which varies between about 0.23 and 0.35, and λ is the wavelength of the light in vacuum). Alternatively, the extinction coefficient of p-type semiconductor layer may be determined based on the location of the delta layer.

A solar cell 100 as described above may be fabricated by any suitable method. In various embodiments, a method of manufacturing such a solar cell comprises providing a substrate 102, depositing a first electrode 104 over the substrate 102, depositing a first portion 106a of a p-type semiconductor absorber layer 106 over the first electrode 104, forming a plasmonic nanostructure 108 over the first portion 106a, depositing a second portion 106b of the p-type semiconductor absorber layer over the plasmonic nanostructure 108, depositing an n-type semiconductor layer 110 over the p-type semiconductor absorber layer 106, and depositing a second electrode 112 over the n-type semiconductor layer 110. The different layers may be deposited by various methods including steps of sputtering, MBE, CVD, evaporation, plating, etc. In some embodiments, one or more sputtering steps may be reactive sputtering.

Alternatively, the layers of the solar cell 100 may be formed in reverse order. In this configuration, a transparent electrode 112 may be deposited over a substrate, followed by depositing an n-type semiconductor layer 110 over the transparent electrode 112, depositing a first portion 106b of a p-type semiconductor absorber layer 106 over the n-type semiconductor layer 112, forming a plasmonic nanostructure 108 on the layer 106b, depositing a second portion 106a of the p-type semiconductor absorber layer over the plasmonic nanostructure 108, and depositing a second electrode 104 over the second portion 106a of the p-type semiconductor absorber layer. The substrate may be a transparent substrate (e.g., glass) or opaque (e.g., metal). If the substrate used is opaque, then the initial substrate may be delaminated after the steps of depositing the stack of the above described layers, and then bonding a glass or other transparent substrate to the transparent electrode 112 of the stack.

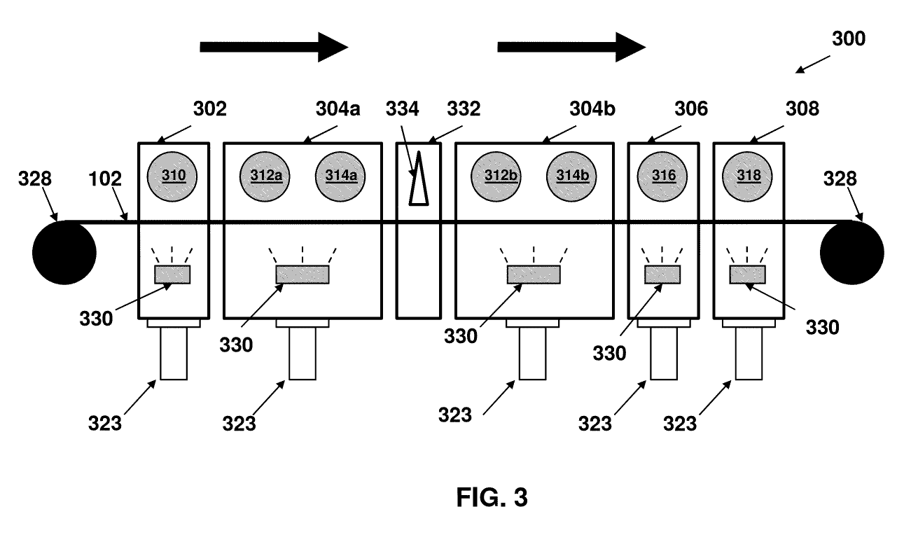

In various embodiments, one or more layers may be deposited by sputtering. FIG. 3 illustrates a simplified schematic diagram of a modular sputtering apparatus 300 that may be used to manufacture solar cells 100. A substrate 102 may be continuously passing through the sputtering apparatus 300 during the sputtering process, moving left to right in the direction of the imaginary arrows above.

The sputtering apparatus 300 may include several process modules 302, 304a, 332, 304b, 306, and 308. The number of process modules may be varied to match the requirements of the device that is being produced. Each module may have a pumping device 323, such as a vacuum pump, for example a high throughput turbomolecular pump, to provide the required vacuum and to handle the flow of process gases during the sputtering operation. Each module may have a number of pumps placed at other locations selected to provide optimum pumping of process gases. The modules may be connected together at slit valves, which contain very narrow low conductance isolation slots to prevent process gases from mixing between modules. These slots may be separately pumped if required to increase the isolation even further. Other module connectors may also be used. Alternatively, a single large chamber may be internally segregated to effectively provide the module regions, if desired. U.S. Published Application No. 2005/0109392 A1 (“Hollars”), filed on Oct. 25, 2004, discloses a vacuum sputtering apparatus having connected modules, and is incorporated herein by reference in its entirety.

The substrate 102 may be moved throughout the machine by rollers 328, or other devices. Additional guide rollers may be used. Some rollers may be bowed to spread the web, some may move to provide web steering, some may provide web tension feedback to servo controllers, and others may be mere idlers to run the web in desired positions.

Heater arrays 330 may be placed in locations where necessary to provide web heating depending upon process requirements. These heaters 330 may be a matrix of high temperature quartz lamps and/or resistance heaters laid out across the width of the web. Infrared sensors may provide a feedback signal to adjust the lamp power and provide uniform heating across the web.

The substrate 102 may be prepared in various ways prior to sputtering, for example by cleaning or preheating. Once the substrate 102 is ready, it may pass into the first process module 302. The first process module 302 may include a sputtering target 310 for sputtering the first electrode 104 onto the substrate 102. The sputtering target 310, as well as the other various sputtering targets in apparatus 300, may be mounted on cylindrical rotary magnetron(s), planar magnetron(s), or RF sputtering sources. Although a single sputtering target 310 for depositing the first electrode 104 is shown in FIG. 3, multiple targets may be used in alternate embodiments, especially if the electrode 104 contains plural sublayers as described above.

The substrate 102 may pass into the next process module 304a for deposition of the first portion 106a of the p-type semiconductor absorber layer 106. In a preferred embodiment shown in FIG. 3, the step of depositing the first portion 106a of p-type semiconductor absorber layer 106 includes reactively alternating current (AC) magnetron sputtering the semiconductor absorber layer from at least one pair of conductive targets 312a and 312b, in a sputtering atmosphere that comprises argon gas and a selenium-containing gas. In some embodiments, the pair of two conductive targets 312a and 312b comprise the same targets. For example, each of the at least two conductive targets 312a and 312b comprises copper, indium and gallium, or comprises copper, indium and aluminum. The selenium-containing gas may be hydrogen selenide or selenium vapor. In other embodiments, targets 312a and 312b may comprise different materials from each other. The heaters 330 maintain the web at the required process temperature, for example, around 400-800° C., for example around 500-700° C., which is preferable for the CIS based alloy deposition.

A plasmonic nanostructure 108 may be formed over the first portion 106a in process module 332. The plasmonic nanostructure 108 may be formed in various ways. For example, prefabricated gold or silver nanoparticles 208 may be deposited via an aerosol spray from a sprayer 334 in a vacuum in process module 332. Alternatively, the nanoparticles 208 may be painted on with a volatile solvent (e.g., acetone) which later evaporates or formed by lithographic techniques (e.g., deposition of a thin metal layer followed by e-beam lithography patterning of the layer into nanoparticles or other nanostructures). In alternate embodiments, the nanoparticles 208 may be formed by evaporating one or more of various metals or metal alloys having plasmonic properties, such as gold, and subsequent nucleation of nanoparticles via Ostwald ripening by controlling deposition pressure and temperature. Surface tension induced agglomeration provides in-situ formed nanoparticles.

A second portion 106b of the p-type semiconductor absorber layer 106 may be deposited in process module 304b. Process module 304b may include sputtering targets 312b and 314b. The second portion 106b may be sputtered as described above with regard to the first portion 106a. The second portion may have a different grain size, porosity and/or composition by controlling the target composition, the selenium pressure or flux, the sputtering pressure and/or temperature or other parameters. The average grain size in layer 106 may range from 0.5 to 1 microns and the porosity may comprise 4 volume % or less.

The substrate 102 may then pass into the process modules 306 and 308, for depositing the n-type semiconductor layer 110, and the transparent top electrode 112, respectively. Process module 306 may include a sputtering target 306. Process module 308 may include a sputtering target 318. Any suitable type of sputtering sources may be used, for example, rotating AC magnetrons, RF magnetrons, or planar magnetrons. Extra magnetron stations (not shown), or extra process modules (not shown) could be added for sputtering the optional one or more AR layers.

The substrate 102 may pass out of the final process module and may be either wound onto a take up spool or sliced into solar cell 100 strings.

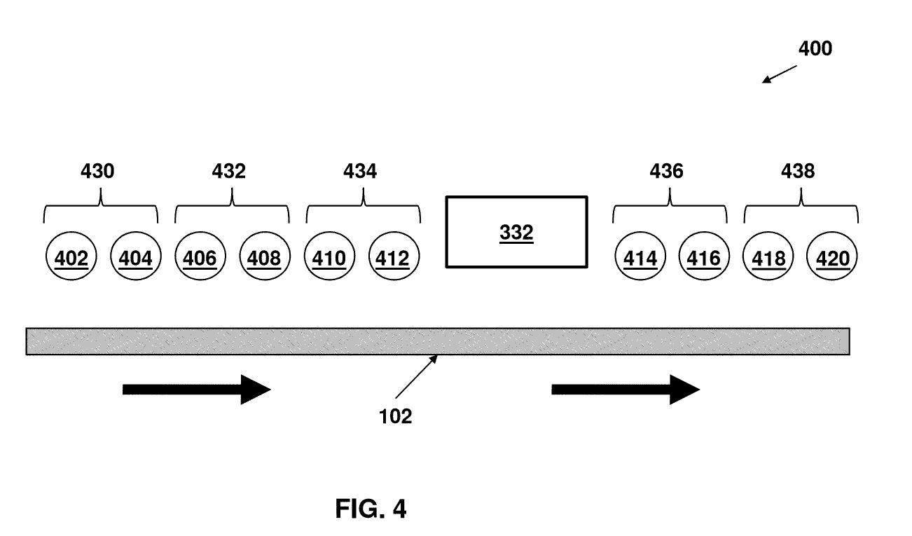

In some embodiments, the p-type semiconductor absorber layer 106 may comprise graded CIS based material. FIG. 4 illustrates a sputtering apparatus 400 with several pairs 430, 432, 434, 436, 438 of sputtering targets 402, 404, 406, 408, 410, 412, 414, 416, 418, 420 for grading the p-type semiconductor during deposition. The process modules 304a and 304b may further comprise additional pairs of targets. The first magnetron pair 430 (with targets 402 and 404) may be used to sputter a layer of copper indium gallium diselenide as the substrate 102 moves in the direction of the imaginary arrows. The remaining pairs of magnetrons targets may sputter deposit layers with increasing amounts of gallium (or aluminum), thus increasing and grading the band gap. The total number of targets pairs may be varied, for example may be 2-10 pairs, such as 3-5 pairs. This will grade the band gap from about 1 eV at the bottom to about 1.3 eV near the top of the layer.

Apparatus 400 may also be used to grade the density of the p-type semiconductor absorber layer 106 such that the index of refraction is varied across the layer. For example, each pair may vary grain size, porosity, or composition of the material deposited to grade the density. The first pair 430 may deposit a relatively low density material. Each subsequent may sputter deposit layers of increasing density such that the density is graded from low at the bottom to high at the top of the layer.

Apparatus 400 may also include a process module 332 for depositing a plasmonic nanostructure 108. The process module 332 may be located between the pairs of magnetrons such that the plasmonic nanostructure 108 is formed within a graded p-type semiconductor absorber layer 106. The process module 332 may form the plasmonic nanostructure in any of the various methods discussed above with regard to FIG. 3.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the solar cells of the present invention.

What is claimed is:

1. A solar cell, comprising:
a first electrode;
at least one first conductivity type semiconductor absorber layer located over the first electrode;
a plasmonic nanostructure located within the semiconductor absorber layer;
a second conductivity type semiconductor layer located over the semiconductor absorber layer; and
a second electrode located over the second conductivity type semiconductor layer.

2. The solar cell of claim 1, wherein:
the semiconductor absorber layer comprises a p-type copper indium selenide (CIS) based alloy material;
the second conductivity type semiconductor layer comprises an n-type semiconductor layer;
the plasmonic nanostructure comprises a delta layer of metal nanoparticles; and
the delta layer of nanoparticles divides the p-type semiconductor absorber layer into a first portion in contact with the n-type semiconductor layer and a second portion, and wherein the first portion has a greater index of refraction than the second portion.

3. The solar cell of claim 2 wherein the p-type semiconductor absorber layer has a graded index of refraction with a greater index of refraction near the n-type semiconductor layer.

4. The solar cell of claim 2, wherein the delta layer is located within the p-type semiconductor absorber layer at a distance from an edge of the p-type semiconductor absorber layer nearest the n-type semiconductor layer, the distance equal to or greater than a sum of a depletion width and a minority carrier diffusion length of the p-type semiconductor layer.

5. The solar cell of claim 4, wherein the n-type semiconductor layer comprises cadmium sulfide and the p-type semiconductor absorber layer comprises CIGS.

6. The solar cell of claim 5, wherein the metal nanoparticles comprise metal or metal alloy having plasmonic properties.

7. The solar cell of claim 6, wherein the metal nanoparticles comprise gold having an average size of less than 500 nm, and the distance comprises 0.3 to 0.7 microns.

8. A method of producing a solar cell, comprising:
providing a substrate;
depositing a first electrode over a substrate;
depositing a first portion of a first conductivity type semiconductor absorber layer over the first electrode;
forming a plasmonic nanostructure over the first portion;
depositing a second portion of the first conductivity type semiconductor absorber layer over the plasmonic nanostructure;
depositing a second conductivity type semiconductor layer over the second portion; and
depositing a second electrode over the second conductivity type semiconductor layer.

9. The method of claim 8, wherein the plasmonic nanostructure comprises a delta layer of metal nanoparticles, the semiconductor absorber layer comprises a p-type copper indium selenide (CIS) based alloy material, and the second conductivity type semiconductor layer comprises an n-type semiconductor layer.

10. The method of claim 9, wherein the metal nanoparticles comprise metal or metal alloy having plasmonic properties.

11. The method of claim 9, wherein the metal nanoparticles comprise gold.

12. The method of claim 8, wherein the first portion is deposited such that it has a greater index of refraction than the second portion.

13. The method of claim 12, wherein the first and second portions of the p-type semiconductor absorber layer are deposited with a graded index of refraction with a greater index of refraction near the n-type semiconductor layer.

14. The method of claim 9, wherein the thickness of the deposited second portion of the p-type semiconductor is the same or greater than a sum of a depletion width and a minority carrier diffusion length of the p-type semiconductor layer.

15. The method of claim 9, wherein the n-type semiconductor layer comprises cadmium sulfide and the p-type semiconductor absorber layer comprises CIGS.

16. A method of producing a solar cell, comprising:
providing a substrate
depositing a first electrode above the substrate;
depositing a second conductivity type semiconductor layer above the first electrode;
depositing a first portion of a first type semiconductor absorber layer above the second conductivity type semiconductor layer;
forming a plasmonic nanostructure above the first portion;
depositing a second portion of the first conductivity type semiconductor absorber layer above the plasmonic nanostructure; and
depositing a second electrode above the second portion.

17. The method of claim 16, wherein the deposited plasmonic nanostructure comprises a delta layer of metal nanoparticles, the semiconductor absorber layer comprises a p-type copper indium selenide (CIS) based alloy material, and the second conductivity type semiconductor layer comprises an n-type semiconductor layer.

18. The method of claim 17, wherein the metal nanoparticles comprise metal or metal alloy having plasmonic properties.

19. The method of claim 17, wherein the first portion is deposited such that it has a greater index of refraction than the second portion, and wherein the thickness of the deposited second portion of the p-type semiconductor is equal to or greater than a sum of a depletion width and a minority carrier diffusion length of the p-type semiconductor layer.

20. The method of claim 19, wherein the n-type semiconductor layer comprises cadmium sulfide and the p-type semiconductor absorber layer comprises CIGS.
